(19) United States
(12) Patent Application Publication
(10) Pub. No.: US 2026/0031168 A1
(43) Pub. Date: Jan. 29, 2026

(54) REDUCING LATENCY FOR DATA RECOVERY PROCEDURES IN MEMORY SYSTEMS

(71) Applicant: Micron Technology, Inc., Boise, ID (US)

(72) Inventors: Akil M, Bangalore (IN); Pranav Tharanath, Bangalore (IN); Amiya Banerjee, Bangalore (IN); Sriraman Sridharan, Hosur (IN)

(21) Appl. No.: 19/270,096

(22) Filed: Jul. 15, 2025

Related U.S. Application Data
(60) Provisional application No. 63/674,920, filed on Jul. 24, 2024.

(51) Int. Cl. G11C 29/12

(52) U.S. Cl. CPC G11C 29/12005

(57) ABSTRACT

Methods, systems, and devices for reducing latency for data recovery procedures in memory systems are described. A memory system may initialize an error recovery procedure in response to a failure to correct data read the memory system during a first read operation, where the first read operation is performed using a first read voltage. In response to the initialization, the memory system may identify, as part of the error recovery procedure, a first read offset from multiple read offsets according to a first syndrome weight generated as part of an attempt to correct the data. Accordingly, the memory system may perform, as part of the error recovery procedure, a second read operation to obtain the data, where the second read operation may be performed using a second read voltage that is the first read voltage modified by the first read offset.

### CROSS REFERENCE

The present application for patent claims priority to U.S. Patent Application No. 63/674,920 by Akil M et al., entitled “REDUCING LATENCY FOR DATA RECOVERY PROCEDURES IN MEMORY SYSTEMS,” filed Jul. 24, 2024, which is assigned to the assignee hereof, and which is expressly incorporated by reference in its entirety herein.

### TECHNICAL FIELD

The following relates to one or more systems for memory, including reducing latency for data recovery procedures in memory systems.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports reducing latency for data recovery procedures in memory systems in accordance with examples as disclosed herein.

FIG. 2 shows an example of a flow diagram that supports reducing latency for data recovery procedures in memory systems in accordance with examples as disclosed herein.

FIG. 3 shows an example of a voltage distribution diagram that supports reducing latency for data recovery procedures in memory systems in accordance with examples as disclosed herein.

FIG. 4 shows a block diagram of a memory system that supports reducing latency for data recovery procedures in memory systems in accordance with examples as disclosed herein.

FIG. 5 shows a flowchart illustrating a method or methods that support reducing latency for data recovery procedures in memory systems in accordance with examples as disclosed herein.

### DETAILED DESCRIPTION

In some cases, due to one or more factors, memory cells of a memory system (e.g., not-AND (NAND) systems) may degrade over time, resulting in the memory system performing various procedures to correct, and in some cases, recover data stored in such memory cells. For example, the memory system may implement a low-density parity check (LDPC) engine, which may utilize LDPC codes to calculate parity bits for data that is to be written to one or more memory cells of the memory system. Accordingly, in response to a read request from a host system, the LDPC engine may utilize such parity bits to verify that the data read from the one or more memory cells is accurate, correct the data read from the one or more memory cells, or both. If the LDPC engine fails to recover the accurate data from the memory cells (e.g., due to the degradation of the memory cells), the memory system may enter a read error handling (REH) procedure, which may involve various steps of calculating and applying different read voltages to the memory cells to recover the data. However, the steps of the REH procedure may result in increased latency in the memory system, for example, due to various complex calculations performed to obtain the accurate read voltages and due to the reapplication of the read voltages to the memory cells to recover the data. Such increased latency may lead to relatively poor performance of the memory system, increased latency in access operations, among other disadvantages.

The techniques, methods, and devices described herein may enable the memory system to maintain one or more mappings that provide an estimated read offset to be applied to the read voltage used to obtain the data, where the estimated read offset may be identified from a syndrome weight associated with the data. For example, in response to entering the REH procedure, the memory system may obtain the syndrome weight from the LDPC engine, where the syndrome weight may be a measurement of a quantity of bit-errors in the data identified by the LDPC engine. According to the syndrome weight, the memory system may obtain the read offset from an associated mapping, modify the original read voltage according to the obtained read offset, and perform a second read operation using the modified read voltage to the memory cells to recover the data. By performing the read operation according to the estimated read offset, the memory system may reduce the latency associated with the REH procedure, for example, by skipping various steps that may involve calculating and applying various read voltages to the memory cells.

In addition to applicability in memory systems as described herein, techniques for reducing latency for data recovery procedures in memory systems may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by identifying a read voltage and/or a read offset to be applied to recover data, where the read voltage may be according to a syndrome weight associated with the data, which may reduce latency associated with data recovery in memory systems, among other benefits.

Features of the disclosure are illustrated and described in the context of systems, devices, and circuits. Features of the disclosure are further illustrated and described in the context of a flow diagram, a voltage distribution diagram, and flowcharts.

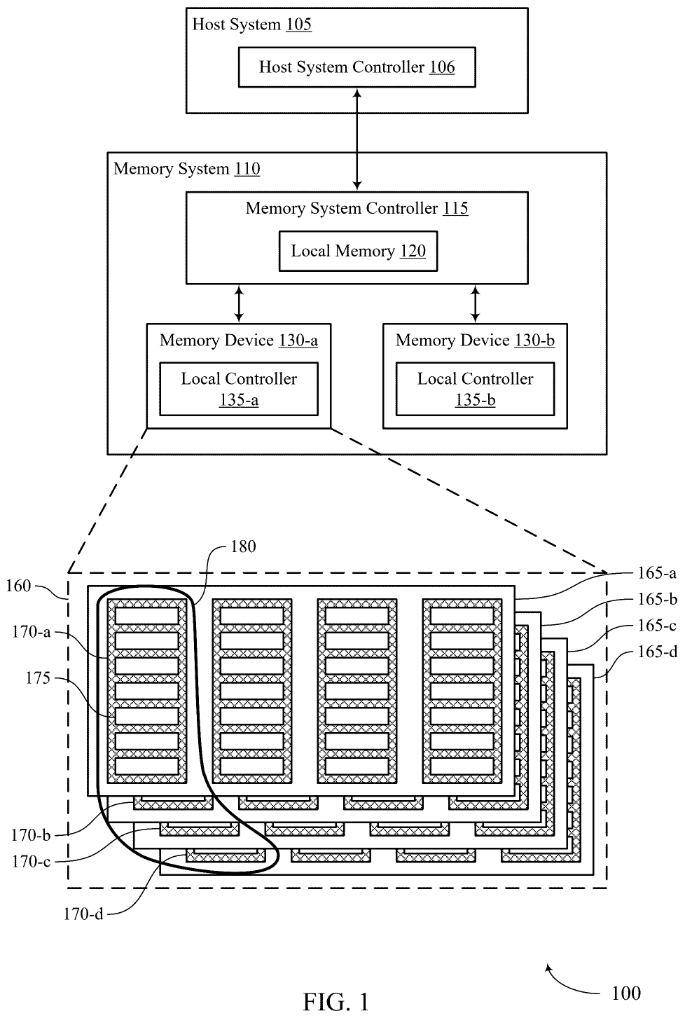

FIG. 1 shows an example of a system 100 that supports reducing latency for data recovery procedures in memory systems in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

In some examples, programmed cells of the memory system 110 may undergo charge loss (e.g., degrade) due to a variety of factors, such as read disturb, program disturb, data retention, program-erase cycling (PEC), temperature variations of the memory system 110, among other examples. Such charge loss may lead to a reduction in the read-window budget (RWB) of the memory cells, since adjacent voltage states capable of being stored by the memory cells may start to overlap. The RWB of a memory cell may refer to the allowable voltage range of a read voltage for reading data from the memory cell and may be defined between two adjacent voltage distributions, which represent different stored data states. Accordingly, the RWB of a memory cell may be instrumental in the operation of the memory cell, as the RWB may determine the margin of error that is tolerated during a read operation. For example, if the RWB is relatively small, the memory system 110 may perform a read operation that may lead to incorrect data being read due to noise or other factors. Conversely, a relatively larger read window budget may lead improvements in the reliability of the memory cell. As such, due to the charge loss, the RWB of memory cells may decrease, leading to a loss of reliability in the memory cells.

In such cases, to recover the data without any errors, the memory system 110 may utilize an LDPC engine to calculate error correction code (ECC) parity bits, which may be programmed along with the data in the memory system 110. As such, the LDPC engine may utilize the LDPC engine to verify the accuracy of the data read from the memory cells and/or correct the data, if bit errors were identified. In some cases, if the LDPC decoder fails to correct the codeword and recover the data, the memory system 110 (e.g., via the firmware) may enter an REH procedure (e.g., flow), which may involve a series of steps arranged (e.g., ordered or performed) in increasing order of latency. Such REH procedures may result in the memory system 110 performing multiple reads to the memory cells, performing complex calculations to estimate the valley bottom (e.g., read voltage, or voltage between two voltage distributions) of the memory cells through different algorithms, or both, which may increase the read latency of the memory system 110 by a few milli-seconds. As such, during the REH procedure, the memory system 110 may pause (e.g., stop or block) all the other operations, thus it may be crucial to reduce the latency of the REH procedure.

The techniques described herein may provide for a relatively low latency step, which estimates the valley bottom positions (e.g., read voltages) without the use of complex computations to improve the read performance. For example, the memory system 110 may maintain one or more mappings that provide the read level offsets, thereby enabling the memory system 110 to avoid certain REH steps, where such read level offsets may be according to the syndrome weights and existing NAND characterization data. Accordingly, the memory system 110 may estimate the read voltage (e.g., valley bottom), identify a read voltage offset, and apply the read voltage offset by utilizing the syndrome weight associated with the data. In such examples, the memory system 110 may correct the data by doing a single read operation, thereby skipping various steps REH procedure. By performing such operations, the memory system 110 may skip the latency-heavy valley searching steps in the REH procedure, thereby improving the read latency.

The system 100 may include any quantity of non-transitory computer readable media that support reducing latency for data recovery procedures in memory systems. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

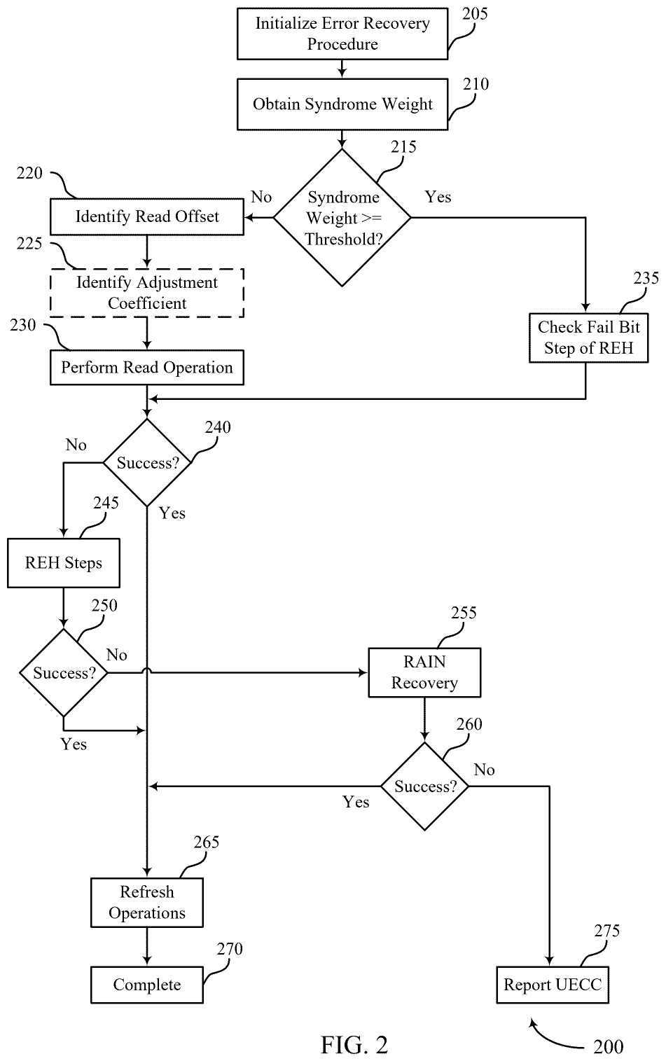

FIG. 2 shows an example of a flow diagram 200 that supports reducing latency for data recovery procedures in memory systems in accordance with examples as disclosed herein. Aspects of the flow diagram 200 may be implemented by one or more controllers, among other components, as described herein with reference to the system 100 of FIG. 1. Additionally, or alternatively, aspects of the flow diagram 200 may be implemented as instructions stored in one or more memories (e.g., firmware stored in one or more memories coupled with the memory system controller 115, a local controller 135, or both). For example, the instructions, when executed by one or more controllers (e.g., the memory system controller 115, a local controller 135, or both), may cause the one or more controllers (or a device or a system) to perform the operations of the flow diagram 200. The techniques described in the context of the flow diagram 200 may enable the memory system 110 to reduce latency associated with REH.

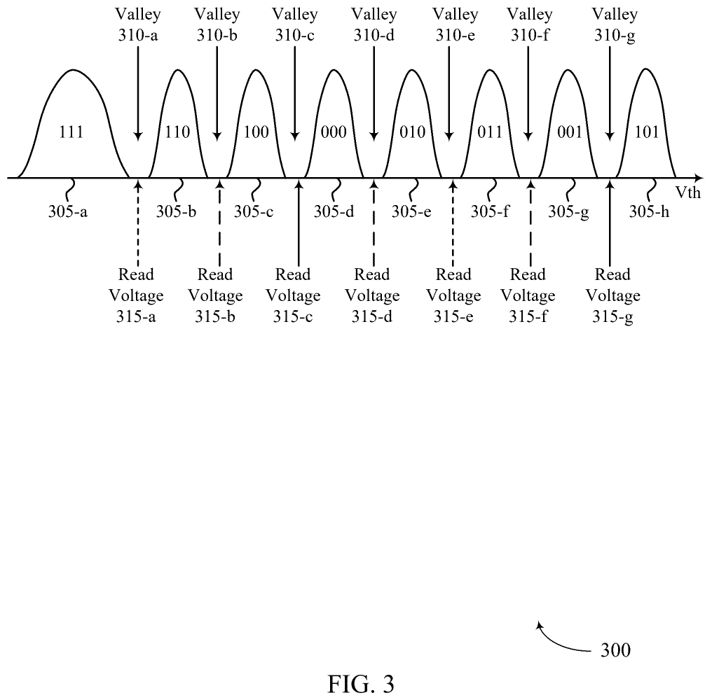

At 205, an error recovery procedure (e.g., REH) may be initialized. For example, the memory system 110 may receive, from the host system 105, a read command to read data stored at a logical block address (LBA) of the memory system 110. In such examples, the memory system controller 115 may perform a first read operation to obtain the data from one or more memory cells associated the LBA, where the first read operation may be performed using a first read voltage (e.g., or a set of first read voltages if performed across multiple memory cells, a read voltage per memory cell). As described herein, each memory cell of the NAND system may be configured as a TLC, which may store up to eight logic states using eight distinct voltage distributions. Accordingly, to read each memory cell, the memory system controller 115 may apply a first read voltage that corresponds to the bottom of a valley between two adjacent voltage distributions, thereby enabling the memory system controller 115 to identify the voltage distribution stored by the memory cell and obtain the logic state. Voltage distributions and valleys may be further described herein with reference to FIG. 3.

In some examples, the memory system controller 115 may obtain the data read from the one or more memory cells associated with the LBA and utilize an LDPC engine to verify and/or correct the data. In such examples, if the LDPC engine fails to decode the data, the LDPC engine may return a failure to decode response and label the data with an uncorrectable error correction code (UECC, sometimes referred to as an uncorrectable error in the data), which may trigger the initialization of the error recovery procedure.

At 210, a syndrome weight associated with the data may be obtained. For example, if the LDPC engine returns the failure to decode response, the memory system controller 115 may obtain a syndrome weight associated with the data from the LDPC engine, where the syndrome weight may indicate a quantity of bit-errors (e.g., quantity of failed decoded bits). That is, the syndrome weight may be an indirect measurement of the quantity of bit-errors that occurred in the data during storage and were identified during the attempt to correct the data. In such examples, a higher syndrome weight value may be associated with a greater quantity of bit-errors in the data, while a lower syndrome weight value may be associated with a fewer quantity of bit-errors in the data.

The range of syndrome weights (e.g., 0-1800) calculated by the LDPC engine may be dissected into three regions: a success region (e.g., an LDPC Decode Success Region having a syndrome weight of 0), a proportional region (e.g., an LDPC Decode Failed-Proportional Region with a syndrome weight between 800-1750), and a saturation region (e.g., an LDPC Decode Failed-Saturation Region with a syndrome weight greater than 1750). The success region may be associated with a quantity of bit-errors that the LDPC decoder is able to correct. For example, although there may not be an upper limit to the quantity of bit-errors that may be corrected by the LDPC engine, the LDPC engine may begin to experience decoding failures after 250 bit-errors per 4 KB codeword. Accordingly, the success region may be associated with 0-250 bit-errors. That is bit-errors between 0 and 250 within a 4 KB codeword may be successfully decoded by the LDPC engine, thus, the LDPC engine may output a syndrome weight of ‘0.’

The proportional region may be a range of syndrome weights where the relationship between the syndrome weight and quantity of bit-errors in the data are proportional. In such examples, the syndrome weight may gradually increase from approximately 800 to a threshold value of 1750, where a syndrome weight of 800 may corresponds to approximately 250 bit-errors and a syndrome weight of 1750 may correspond to approximately 1750 bit-errors. As described herein, the memory system controller 115 may maintain one or more mappings for estimating read offsets according to syndrome weights, where the syndrome weights identified (e.g., used or stored) in the mapping may correspond to the syndrome weights within the proportional region. That is, because the quantity of bit-errors identified in the data are proportional to the syndrome weights in the proportional region, the memory system controller 115 may utilize the relationship to identify and estimate the read offset adjustments that may be used to correct the errors in the data. Such mappings between the syndrome weights and read offsets may be further described herein with reference to the operations at 220.

The saturation region may include syndrome weights associated bit-errors greater than or equal to 1250 bit-errors, where, in such a region, the memory system controller 115 may be unable to identify a read offset voltage. For example, beyond 1250 bit-errors, the syndrome weight calculated by the LDPC engine may begin to saturate (e.g., level off or become negligible) at 1750 bit-errors, such that as the quantity of bit-errors increases in the data, the syndrome weight reported by the LDPC does not have a visible increase. In the saturation region, the memory system 110 may be unable to predict the read offset (e.g., read adjustment) because the quantity of bit errors associated with a syndrome weight of 1750 may be anywhere between 1250 bit-errors to the maximum codeword size (e.g., 4 KB), thereby rending a mapping indefinite. That is, the memory system controller 115 may not maintain mappings (e.g., look-up tables (LUTs)) between read offsets and syndrome weights above 1750 because a syndrome weight of over 1750 may not be associated with a specific bit-error range.

Accordingly, because the memory system 110 may employ various error prevention algorithms, such as block family error avoidance, read disturb handling, media scans, among other example, the probability of a UECC error encountered during REH may be greater in the proportional region as compared to the saturation region. That is, the LDPC engine may encounter syndrome weights within the proportional region with a greater likelihood than syndrome weights within the saturation region. As such, if the memory system controller 115 is enabled to correct the bit-errors associated with the proportional region, the memory system controller 115 may be able to correct the majority of probable UECCs encountered during operation.

At 215, the syndrome weight may be compared to a threshold. For example, in response to obtaining the syndrome weight, the memory system controller 115 may compare the syndrome weight to a threshold (e.g., 1750), where the threshold may indicate whether the syndrome weight encountered by the LDPC encoder is associated with the saturation region or the proportional region. Accordingly, if the syndrome weight is less than the threshold, the memory system controller 115 may determine that the syndrome weight is within the proportional region and proceed to perform the operations at 220. Alternatively, if the syndrome weight is greater than the threshold, the memory system controller 115 may determine that the syndrome weight is within the saturation region and proceed to perform the operations at 235. That is, once the syndrome weight has saturated, the memory system controller 115 may be unable to predict which read offset shift is to be applied, and thus may proceed to the operations at 235.

At 220, a read offset may be identified. That is, the memory system controller 115 may maintain one or more mappings between the syndrome weight obtained from the LDPC engine and a read offset to be applied to the first read voltage. For example, the memory system controller 115 may utilize a relationship between the syndrome weight and read offsets (quantized in terms of digital to analog (DAC) conversion) to predict the read level shift to be applied for the second read operation at 230. In some examples, the mappings may be hardcoded within the memory system controller 115 according to calculations performed on data collected across various memory systems. Alternatively, the memory system controller 115 may update and maintain the mappings according to various characterization data (e.g., temperature variation, read disturbs, PECs, among other examples) observed through operation of the memory system 110.

In such examples, the memory system controller 115 may maintain a respective mapping between syndrome weights and read offsets for each of a subset of multiple voltage valleys of a memory cell. For example, the memory system controller 115 may maintain a respective mapping between syndrome weights and read offsets for upper valleys (e.g., valleys between higher voltage distributions) of the voltage distribution within a memory cell, which may be referred to as a level 5 valley, a level 6 valley, and a level 7 valley. Such upper valleys may be further described herein with respect to FIG. 3.

Additionally, the memory system controller 115 may maintain, for each of the lower page, upper page, and extra pages of a logical page, a respective mapping between read offsets and the syndrome weight for level 5 valleys, level 6 valleys, and level 7 valleys (e.g., nine mappings or LUTs). The memory system controller 115 may maintain each mapping (e.g., LUT) in the local memory 120 (e.g., SRAM), where each mapping may be limited in size (e.g., approximately 20 bytes each). As an illustrative example, the memory system controller 115 may maintain, for an upper page, a first mapping between the syndrome weight and read offsets for the level 5 valley, a second mapping between the syndrome weight and read offsets for the level 6 valley, and maintain a third mapping between the syndrome weight and read offsets for the level 7 valley. Similar mappings may be maintained for the lower page and extra page of a logical page. Table 2 illustrates a mapping between the syndrome weight and read offsets for level 6 valleys of the upper page.

TABLE 1
Read Offsets for Level 6 Valley of Upper Page

| Syndrome | Read Offset |
|---|---|
| Weight Range | (DAC) |
| 800-850 | −33 |
| 850-900 | −33 |
| 900-950 | −34 |
| 950-1000 | −35 |
| 1000-1050 | −35 |
| 1050-1100 | −35 |
| 1100-1150 | −35 |
| 1150-1200 | −35 |
| 1200-1250 | −36 |
| 1250-1300 | −36 |
| 1300-1350 | −37 |
| 1350-1400 | −37 |
| 1400-1450 | −38 |
| 1450-1500 | −39 |
| 1500-1550 | −39 |
| 1550-1600 | −40 |
| 1600-1650 | −41 |
| 1650-1700 | −42 |
| 1700-1750 | −43 |

Accordingly, on encountering a read error, the memory system controller 115 may obtain the syndrome weight from the read failure at 210, determine whether the syndrome weight is in the proportional range (e.g., below a threshold of 1750), and determine the read offset to use. To identify the read offset, the memory system controller 115 may determine the voltage valley associated with the first read voltage, identify the portion of the logical page associated with the memory cell (e.g., lower page, upper page, or extra page), and utilize the identified voltage valley and portion of the logical page to identify the correct mapping. In response to identifying the correct mapping, the memory system controller 115 may utilize the syndrome weight obtained at 210 to identify the read offset at 220.

At 225, an adjustment coefficient may be identified. For example, as described herein, the memory system controller 115 may maintain a mapping between the syndrome weight and the read offset for a subset of multiple valleys (e.g., upper valleys) between upper voltage distributions capable of being stored by a memory cell. In such examples, if the memory system controller 115 identifies that the first read voltage is associated with a valley between two lower voltage distributions (e.g., a lower valley), the memory system controller 115 may utilize an adjustment coefficient that represents a linear relationship between the read offset of the upper valleys and the read offset of the lower valleys. Accordingly, if the memory system controller 115 identifies that the first read voltage is associated with a lower valley, the memory system controller 115 may utilize a mapping to identify the adjustment coefficient. Techniques describing the adjustment coefficient and obtaining the adjustment coefficient may be further described herein with reference to FIG. 3.

At 230, a second read operation may be performed. For example, in response to identifying the read offset at 220 and optionally identifying the adjustment coefficient at 235, the memory system controller 115 may perform the second read operation using a second read voltage, where the second read voltage may be the first read voltage modified by the read offset, the adjustment coefficient, or both.

As described herein, the memory system controller 115 may perform the operations at 220, 225, and 230 for each memory cell read from during the first read operation at 205. For example, if the data is stored across multiple memory cells, the memory system controller 115 may identify read offset and/or adjustment coefficients to be used for a respective read voltage for each of the multiple memory cells.

At 235, a check fail-bit step of the REH procedure may be performed. For example, in response to determining that the syndrome weight is greater than the threshold (e.g., 1750), the memory system controller 115 may skip one or more steps of the REH procedure, such as a re-read step, read-last step, bin retry steps, pre-fix read retry steps, among other examples, and perform the check fail-bit step. During the check fail bit step, the LDPC engine or other ECC engines may utilize redundancy information or ECC codes stored with the data to recover the data. In such examples, by skipping to the check fail-bit step, the memory system controller 115 may avoid several of the initial REH steps by taking an informed decision according to the syndrome weight and may recover errors up to a first loop of the check fail-bit step (e.g., check fail bit stage).

At 240, it may be determined whether the data was successfully recovered. For example, the memory system controller 115 may determine whether the data was successfully recovered by the check fail-bit step performed at 235 or by the read operation performed at 230. If the data was successfully recovered, the memory system controller 115 may proceed to perform the operations at 265. Alternatively, if the data was not successfully recovered, the memory system controller 115 may proceed to perform the operations at 245.

At 245, one or more REH steps may be performed. For example, in response to determining that data was unsuccessfully recovered, the memory system controller 115 may perform various steps of the REH procedure. In one example, the memory system controller 115 may being to perform a read last step of the REH procedure utilizing the read base offsets identified from the mappings (e.g., using the predicted read offset shift identified at 220, which may facilitate convergence to recover the data) and progress with read recovery. In another example, if the read operation at 230 fails, the memory system controller 115 may proceed to perform the check fail bit steps of REH, thus skipping various REH steps, such as a re-read step, read-last step, bin retry steps, pre-fix read retry steps, among other examples.

At 250, it may be determined whether the data was successfully recovered. For example, in response to performing the one or more REH steps at 245, the memory system controller 115 may determine whether the data was successfully recovered. If the data was successfully recovered, the memory system controller 115 may proceed to perform the operations at 265. Alternatively, if the data was not successfully recovered at 245, the memory system controller 115 may proceed to perform the operations at 255.

At 255, a redundant array of independent NAND (RAIN) procedure may be performed. For example, if the data has not been recovered after performing the operations at 230, 235, and 245, the memory system controller 115 may perform a RAIN procedure to recover the data. In the RAIN procedure, the memory system controller 115 may obtain redundant data stored across multiple NAND dies and use the redundant data to reconstruct the corrupted data.

At 260, it may be determined whether the data was successfully recovered by the RAIN procedure. For example, the memory system controller 115 may determine whether the data was successfully recovered using the RAIN procedures at 255. If the data was successfully recovered, the memory system controller 115 may proceed to perform the operations at 265. Alternatively, if the data was not successfully recovered, the memory system controller 115 may proceed to perform the operations at 275.

At 265, a refresh operation may be scheduled. For example, in response to successfully recovering the data (e.g., at 230, 235, 245, or 255) the data may be returned to the host system 105 and the memory system controller 115 may schedule a refresh operation to be performed on one or more blocks of data associated with the LBA. In such examples, in response to recovering the data, the memory system controller 115 may proceed to perform various other access operations within the memory system 110. At 270, the REH operation may be completed. For example, in response to performing the operations at 265, the memory system controller 115 may complete the REH procedure. At 275, the UECC may be reported. For example, in response to unsuccessfully obtaining (e.g., recovering) the data, the memory system controller 115 may proceed to report the UECC to the host system 105.

FIG. 3 shows an example of a voltage distribution diagram 300 that supports reducing latency for data recovery procedures in memory systems in accordance with examples as disclosed herein. Aspects of the voltage distribution diagram 300 may be implemented by the system 100 and the flow diagram 200. The techniques described in the context of the voltage distribution diagram 300 may enable the memory system controller 115 to identify the adjustment coefficient, as described herein with reference to the operations at 225 of FIG. 2.

The voltage distribution diagram 300 may illustrate voltage distribution 305 utilized in memory cells (e.g., NAND TLC memory cells), where each voltage distribution may be associated with a respective logic state. For example, the voltage distribution diagram 300 of a TLC NAND memory cell may store up to eight logic states and include a voltage distribution 305-a corresponding to a logic state of ‘111’, a voltage distribution 305-b corresponding to a logic state of ‘110’, a voltage distribution 305-c corresponding to a logic state of ‘100’, a voltage distribution 305-d corresponding to a logic state of ‘000’, a voltage distribution 305-e corresponding to a logic state of ‘010’, a voltage distribution 305-f corresponding to a logic state of ‘011’, a voltage distribution 305-g corresponding to a logic state of ‘001’, and a voltage distribution 305-h corresponding to a logic state of ‘101’.

Each voltage distribution 305 may be separated from each other via a valley 310 (e.g., the voltage distribution 305-a and 305-b may be separated via a valley 310-a, while the voltage distributions 305-b and 305-c may be separated via a valley 310-b, and so on using the valleys 310-c, 310-d, 310-c, 310-f, and 310-g). Accordingly, to write a logic state to a memory cell, the memory system controller 115 may apply a voltage associated with the corresponding voltage distribution 305 to the memory cell. To read the logic state from memory cell, the memory system controller 115 may apply a read voltage 315 (e.g., read voltages 315-a, 315-b, 315-c, 315-d, 315-c, 315-f, and 315-g), which may correspond to the bottom of the associated valley 310 (in an ideal situation). As an illustrative example, to write a ‘111’ to the memory cell, the memory system controller may apply a voltage to the memory cell that corresponds to the voltage distribution 305-a. To read the logic state ‘111’, the memory system controller 115 may apply the read voltage 315-a to the memory cell, which may correspond to the bottom of the valley 310-a, among other read voltages that may be applied at the bottoms of other valleys to aid in determining which state is stored.

As described herein with reference to the operations at 220 of FIG. 2, the memory system controller 115 may maintain multiple mappings between syndrome weights and read offsets for a subset of the valleys 310. For example, the memory system controller 115 may maintain a respective mapping between syndrome weights and read offset for the valleys 310-e (e.g., level 5), 310-f (e.g., level 6), and 310-g (e.g., level 7) for each of the lower page, upper page, and extra pages of a logical page (e.g., nine mappings or LUTs).

Accordingly, as described herein with reference to operations at 225 of FIG. 2, the memory system controller 115 may maintain a respective mapping of adjustment coefficients between the higher valleys (e.g., valley 310-e, valley 310-f, and valley 310-g) and the lower valleys (e.g., valleys 310-a, 310-b, 310-c, and 310-d) for each of the lower page, upper page, and extra pages of a logical page. Such mappings may be in accordance with a linear relationship between the read offsets for a higher valley 310 (e.g., a higher valley adjustment) and read offsets for a lower valley (e.g., a lower valley adjustment) to reach the valley bottom (e.g., identify the appropriate read voltage 315), where such a linear relationship may be characterized by an adjustment coefficient (e.g., linear coefficient).

In such examples, the linear relation between a first higher valley 310 may be valid for a subset of the lower valleys 310. For example, the read offset associated with the valley 310-g may have a linear relationship with the read offset associated with the valley 310-c, while the read offset of the valley 310-f may have a linear relationship with the read offsets associated with the valleys 310-d and 310-b. Likewise, the read offsets associated with the valley 310-e may have a linear relationship with the read offsets of the valley 310-a. Additionally, the adjustment coefficients between the a higher valley 310 and a lower valley 310 may also vary according to the word line grouping (WGR) of the page being read.

As an illustrative example, the memory system controller 115 may maintain, for an upper page of a logical page, a first mapping indicating a first set of adjustment coefficients for the read offset between the valley 310-e and the valley 310-a according to WGR, a second mapping indicating a second set of adjustment coefficients for the read offset between the valley 310-f and the valley 310-b according to WGR and a third set of adjustment coefficients for the read offset between the valley 310-f and the valley 310-d according to the WGR, and a third mapping indicating a fourth set of adjustment coefficients for the read offset between the valley 310-e and the valley 310-a according to the WGR. The memory system controller 115 may maintain similar mappings (e.g., LUTs) for each of the lower page and extra page of a logical page. Table 2 illustrates an example of the adjustment coefficients for the valley 310-f of an upper page.

TABLE 2
Coefficients for Valley 310-f

| | Valley 310-b | Valley 310-d |
|---|---|---|
| WGR | Coefficient | Coefficient |
| 0 | 0.29 | 0.6 |
| 1 | 0.29 | 0.63 |
| 2 | 0.24 | 0.62 |
| 3 | 0.24 | 0.64 |
| 4 | 0.22 | 0.63 |
| 5 | 0.29 | 0.64 |
| 6 | 0.29 | 0.65 |
| 7 | 0.32 | 0.66 |
| 8 | 0.32 | 0.67 |
| 9 | 0.36 | 0.68 |
| 10 | 0.33 | 0.68 |
| 11 | 0.32 | 0.67 |
| 12 | 0.33 | 0.67 |
| 13 | 0.33 | 0.68 |
| 14 | 0.32 | 0.67 |
| 15 | 0.36 | 0.68 |

Accordingly, using such mappings, the memory system controller 115 may be able to identify the read voltage offset for each of the valleys 310-a through 310-d to recover the data, as described herein with reference to the operations at 220-230 of FIG. 2. As an illustrative example, at the operations of 220 of FIG. 2, the memory system controller 115 may identify that, during the first read operation on a first memory cell, the read voltage 315-d was applied. Accordingly, the memory system controller 115 may identify that the valley 310-d is associated with the read voltage 315-d and determine that the valley 310-d has a linear relationship with the valley 310-f. In response to identifying the valley 310-f, the memory system controller 115 may identify, from the multiple mappings (e.g., LUTs) stored in the local memory 120, the correct mapping for the valley 310-f according to the portion (e.g., lower page, upper page, or extra page) of the LBA and obtain, using identified mapping, the read offset associated with the valley 310-f according to the identified syndrome weight.

In response to obtaining the read offset for the valley 310-f, at the operations of 225 of FIG. 2, the memory system controller 115 may identify the correct adjustment coefficient mapping (e.g., LUT) for the valley 310-f according to the portion of the LBA. In response to identifying the adjustment coefficient mapping, the memory system controller 115 may determine the adjustment coefficient between the valley 310-d and the valley 310-f to be applied to the identified read offset according to the WGR associated with the memory cell. In this way, the memory system controller 115 may utilize the mappings to obtain the adjustment coefficients, apply the correct read offset to the first read voltage, and recover the data.

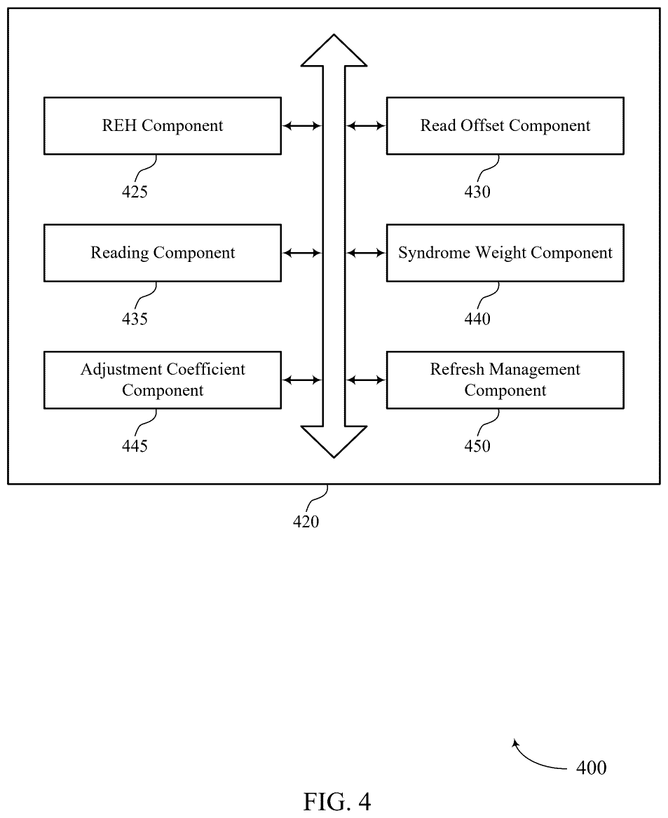

FIG. 4 shows a block diagram 400 of a memory system 420 that supports reducing latency for data recovery procedures in memory systems in accordance with examples as disclosed herein. The memory system 420 may be an example of aspects of a memory system as described with reference to FIGS. 1 through 3. The memory system 420, or various components thereof, may be an example of means for performing various aspects of reducing latency for data recovery procedures in memory systems as described herein. For example, the memory system 420 may include a REH component 425, a read offset component 430, a reading component 435, a syndrome weight component 440, an adjustment coefficient component 445, a refresh management component 450, or any combination thereof. Each of these components, or components of subcomponents thereof (e.g., one or more processors, one or more memories), may communicate, directly or indirectly, with one another (e.g., via one or more buses).

The REH component 425 may be configured as or otherwise support a means for initializing an error recovery procedure in response to a failure to correct data read the memory system during a first read operation, the first read operation being performed using a first read voltage. The read offset component 430 may be configured as or otherwise support a means for identifying, as part of the error recovery procedure, a first read offset from a plurality of read offsets according to a first syndrome weight generated as part of an attempt to correct the data. The reading component 435 may be configured as or otherwise support a means for performing, as part of the error recovery procedure, a second read operation to obtain the data, where the second read operation is performed using a second read voltage that includes the first read voltage modified by the first read offset.

In some examples, the syndrome weight component 440 may be configured as or otherwise support a means for determining that the first syndrome weight is less than a threshold, where identifying the first read offset from the plurality of read offsets is in accordance with the first syndrome weight being less than the threshold.

In some examples, the REH component 425 may be configured as or otherwise support a means for skipping one or more initial steps of the error recovery procedure in accordance with the first syndrome weight being less than the threshold, where identifying the first read offset is in accordance with skipping the one or more initial steps of the error recovery procedure.

In some examples, to support identifying the first read offset, the read offset component 430 may be configured as or otherwise support a means for identifying, from a plurality of mappings, a first mapping including the plurality of read offsets in accordance with a voltage distribution that represents the data stored at a memory cell, in accordance with a portion of a logical address associated with the memory cell, or both, where identifying the first read offset from the plurality of read offsets is in accordance with identifying the first mapping including the plurality of read offsets.

In some examples, each of the plurality of mappings are include respective pluralities of read offsets indexed by a respective range of syndrome weight values, each of the plurality of mappings are associated with a respective portion of the logical address, and each of the plurality of mappings are associated with a respective upper voltage valley of a plurality of upper voltage valleys, the respective upper voltage valley being between two voltage distributions.

In some examples, each of the plurality of mappings are stored in volatile memory of the memory system.

In some examples, the adjustment coefficient component 445 may be configured as or otherwise support a means for adjusting the first read offset by a first adjustment coefficient of a plurality of adjustment coefficients, where performing the second read operation is in accordance with adjusting the first read offset by the first adjustment coefficient.

In some examples, the adjustment coefficient component 445 may be configured as or otherwise support a means for identifying a mapping including the plurality of adjustment coefficients in accordance with a portion of a logical address associated with the data, in accordance with a voltage valley between two voltage distributions of a memory cell that stores the data, or both, where one of the two voltage distributions of the memory cell represents the data. In some examples, the adjustment coefficient component 445 may be configured as or otherwise support a means for identifying, from the plurality of adjustment coefficients included in the mapping, the first adjustment coefficient in accordance with a word line group associated with the memory cell.

In some examples, the first adjustment coefficient defines a linear relationship between the voltage valley between the two voltage distributions of the memory cell and a corresponding second voltage valley between two other voltage distributions of the memory cell. In some examples, the two other voltage distributions are greater than the two voltage distributions.

In some examples, the REH component 425 may be configured as or otherwise support a means for initializing a second error recovery procedure in response to a failure to correct second data that is read from the memory system during a third read operation, the third read operation being performed using a third read voltage. In some examples, the syndrome weight component 440 may be configured as or otherwise support a means for determining that a second syndrome weight associated with the second data fails to satisfy a threshold. In some examples, the REH component 425 may be configured as or otherwise support a means for skipping one or more initial steps of the second error recovery procedure in accordance with the second syndrome weight failing to satisfy the threshold. In some examples, the REH component 425 may be configured as or otherwise support a means for performing a check fail-bit step of the second error recovery procedure in accordance with the second syndrome weight failing to satisfy the threshold and in accordance with skipping the one or more initial steps of the second error recovery procedure.

In some examples, the REH component 425 may be configured as or otherwise support a means for performing, as part of the error recovery procedure, a check fail-bit procedure in response to the second read operation failing to obtain the data.

In some examples, the refresh management component 450 may be configured as or otherwise support a means for performing a refresh operation on a block of memory cells in accordance with successfully reading the data during the second read operation.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

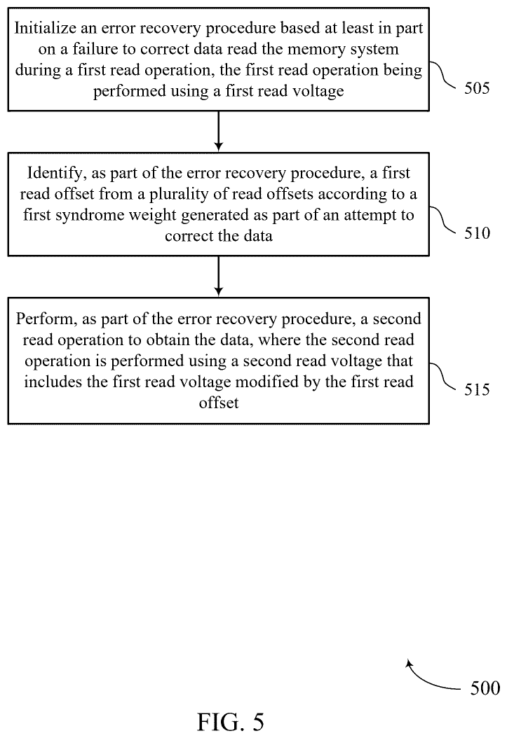

FIG. 5 shows a flowchart illustrating a process 500 that supports reducing latency for data recovery procedures in memory systems in accordance with examples as disclosed herein. The operations of process 500 may be implemented by a memory system or its components as described herein. For example, the operations of process 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the process may include initializing an error recovery procedure in response to a failure to correct data read the memory system during a first read operation, the first read operation being performed using a first read voltage. In some examples, aspects of the operations of 505 may be performed by a REH component 425 as described with reference to FIG. 4.

At 510, the process may include identifying, as part of the error recovery procedure, a first read offset from a plurality of read offsets according to a first syndrome weight generated as part of an attempt to correct the data. In some examples, aspects of the operations of 510 may be performed by a read offset component 430 as described with reference to FIG. 4.

At 515, the process may include performing, as part of the error recovery procedure, a second read operation to obtain the data, where the second read operation is performed using a second read voltage that includes the first read voltage modified by the first read offset. In some examples, aspects of the operations of 515 may be performed by a reading component 435 as described with reference to FIG. 4.

In some examples, an apparatus as described herein may perform a process or processes, such as the process 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for initializing an error recovery procedure in response to a failure to correct data read the memory system during a first read operation, the first read operation being performed using a first read voltage; identifying, as part of the error recovery procedure, a first read offset from a plurality of read offsets according to a first syndrome weight generated as part of an attempt to correct the data; and performing, as part of the error recovery procedure, a second read operation to obtain the data, where the second read operation is performed using a second read voltage that includes the first read voltage modified by the first read offset.

Aspect 2: The method, apparatus, or non-transitory computer-readable medium of aspect 1, further including operations, features, circuitry, logic, means, or instructions, or any combination thereof for determining that the first syndrome weight is less than a threshold, where identifying the first read offset from the plurality of read offsets is in accordance with the first syndrome weight being less than the threshold.

Aspect 3: The method, apparatus, or non-transitory computer-readable medium of aspect 2, further including operations, features, circuitry, logic, means, or instructions, or any combination thereof for skipping one or more initial steps of the error recovery procedure in accordance with the first syndrome weight being less than the threshold, where identifying the first read offset is in accordance with skipping the one or more initial steps of the error recovery procedure.

Aspect 4: The method, apparatus, or non-transitory computer-readable medium of any of aspects 1 through 3, where identifying the first read offset includes operations, features, circuitry, logic, means, or instructions, or any combination thereof for identifying, from a plurality of mappings, a first mapping including the plurality of read offsets in accordance with a voltage distribution that represents the data stored at a memory cell, in accordance with a portion of a logical address associated with the memory cell, or both, where identifying the first read offset from the plurality of read offsets is in accordance with identifying the first mapping including the plurality of read offsets.

Aspect 5: The method, apparatus, or non-transitory computer-readable medium of aspect 4, where each of the plurality of mappings are include respective pluralities of read offsets indexed by a respective range of syndrome weight values, each of the plurality of mappings are associated with a respective portion of the logical address, and each of the plurality of mappings are associated with a respective upper voltage valley of a plurality of upper voltage valleys, the respective upper voltage valley being between two voltage distributions.

Aspect 6: The method, apparatus, or non-transitory computer-readable medium of any of aspects 4 through 5, where each of the plurality of mappings are stored in volatile memory of the memory system.

Aspect 7: The method, apparatus, or non-transitory computer-readable medium of any of aspects 1 through 6, further including operations, features, circuitry, logic, means, or instructions, or any combination thereof for adjusting the first read offset by a first adjustment coefficient of a plurality of adjustment coefficients, where performing the second read operation is in accordance with adjusting the first read offset by the first adjustment coefficient.

Aspect 8: The method, apparatus, or non-transitory computer-readable medium of aspect 7, further including operations, features, circuitry, logic, means, or instructions, or any combination thereof for identifying a mapping including the plurality of adjustment coefficients in accordance with a portion of a logical address associated with the data, in accordance with a voltage valley between two voltage distributions of a memory cell that stores the data, or both, where one of the two voltage distributions of the memory cell represents the data and identifying, from the plurality of adjustment coefficients included in the mapping, the first adjustment coefficient in accordance with a word line group associated with the memory cell.

Aspect 9: The method, apparatus, or non-transitory computer-readable medium of aspect 8, where the first adjustment coefficient defines a linear relationship between the voltage valley between the two voltage distributions of the memory cell and a corresponding second voltage valley between two other voltage distributions of the memory cell and the two other voltage distributions are greater than the two voltage distributions.

Aspect 10: The method, apparatus, or non-transitory computer-readable medium of any of aspects 1 through 9, further including operations, features, circuitry, logic, means, or instructions, or any combination thereof for initializing a second error recovery procedure in response to a failure to correct second data that is read from the memory system during a third read operation, the third read operation being performed using a third read voltage; determining that a second syndrome weight associated with the second data fails to satisfy a threshold; skipping one or more initial steps of the second error recovery procedure in accordance with the second syndrome weight failing to satisfy the threshold; and performing a check fail-bit step of the second error recovery procedure in accordance with the second syndrome weight failing to satisfy the threshold and in accordance with skipping the one or more initial steps of the second error recovery procedure.

Aspect 11: The method, apparatus, or non-transitory computer-readable medium of any of aspects 1 through 10, further including operations, features, circuitry, logic, means, or instructions, or any combination thereof for performing, as part of the error recovery procedure, a check fail-bit procedure in response to the second read operation failing to obtain the data.

Aspect 12: The method, apparatus, or non-transitory computer-readable medium of any of aspects 1 through 11, further including operations, features, circuitry, logic, means, or instructions, or any combination thereof for performing a refresh operation on a block of memory cells in accordance with successfully reading the data during the second read operation.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memories storing processor-executable code; and
one or more processors coupled with the one or more memories and individually or collectively operable to execute the code to cause the memory system to:
initialize an error recovery procedure in response to a failure to correct data read the memory system during a first read operation, the first read operation being performed using a first read voltage;
identify, as part of the error recovery procedure, a first read offset from a plurality of read offsets according to a first syndrome weight generated as part of an attempt to correct the data; and
perform, as part of the error recovery procedure, a second read operation to obtain the data, wherein the second read operation is performed using a second read voltage that comprises the first read voltage modified by the first read offset.

2. The memory system of claim 1, wherein the one or more processors are individually or collectively further operable to execute the code to cause the memory system to:
determine that the first syndrome weight is less than a threshold, wherein identifying the first read offset from the plurality of read offsets is in accordance with the first syndrome weight being less than the threshold.

3. The memory system of claim 2, wherein the one or more processors are individually or collectively further operable to execute the code to cause the memory system to:
skip one or more initial steps of the error recovery procedure in accordance with the first syndrome weight being less than the threshold, wherein identifying the first read offset is in accordance with skipping the one or more initial steps of the error recovery procedure.

4. The memory system of claim 1, wherein, to identify the first read offset, the one or more processors are individually or collectively operable to execute the code to cause the memory system to:
identify, from a plurality of mappings, a first mapping comprising the plurality of read offsets in accordance with a voltage distribution that represents the data stored at a memory cell, in accordance with a portion of a logical address associated with the memory cell, or both, wherein identifying the first read offset from the plurality of read offsets is in accordance with identifying the first mapping comprising the plurality of read offsets.

5. The memory system of claim 4, wherein each of the plurality of mappings are comprise respective pluralities of read offsets indexed by a respective range of syndrome weight values, each of the plurality of mappings are associated with a respective portion of the logical address, and each of the plurality of mappings are associated with a respective upper voltage valley of a plurality of upper voltage valleys, the respective upper voltage valley being between two voltage distributions.

6. The memory system of claim 4, wherein each of the plurality of mappings are stored in volatile memory of the memory system.

7. The memory system of claim 1, wherein the one or more processors are individually or collectively further operable to execute the code to cause the memory system to:
adjust the first read offset by a first adjustment coefficient of a plurality of adjustment coefficients, wherein performing the second read operation is in accordance with adjusting the first read offset by the first adjustment coefficient.

8. The memory system of claim 7, wherein the one or more processors are individually or collectively further operable to execute the code to cause the memory system to:
identify a mapping comprising the plurality of adjustment coefficients in accordance with a portion of a logical address associated with the data, in accordance with a voltage valley between two voltage distributions of a memory cell that stores the data, or both, wherein one of the two voltage distributions of the memory cell represents the data; and
identify, from the plurality of adjustment coefficients included in the mapping, the first adjustment coefficient in accordance with a word line group associated with the memory cell.

9. The memory system of claim 8, wherein:
the first adjustment coefficient defines a linear relationship between the voltage valley between the two voltage distributions of the memory cell and a corresponding second voltage valley between two other voltage distributions of the memory cell, and
the two other voltage distributions are greater than the two voltage distributions.

10. The memory system of claim 1, wherein the one or more processors are individually or collectively further operable to execute the code to cause the memory system to:
initialize a second error recovery procedure in response to a failure to correct second data that is read from the memory system during a third read operation, the third read operation being performed using a third read voltage;
determine that a second syndrome weight associated with the second data fails to satisfy a threshold;
skip one or more initial steps of the second error recovery procedure in accordance with the second syndrome weight failing to satisfy the threshold; and
perform a check fail-bit step of the second error recovery procedure in accordance with the second syndrome weight failing to satisfy the threshold and in accordance with skipping the one or more initial steps of the second error recovery procedure.

11. The memory system of claim 1, wherein the one or more processors are individually or collectively further operable to execute the code to cause the memory system to:
perform, as part of the error recovery procedure, a check fail-bit procedure in response to the second read operation failing to obtain the data.

12. The memory system of claim 1, wherein the one or more processors are individually or collectively further operable to execute the code to cause the memory system to:
perform a refresh operation on a block of memory cells in accordance with successfully reading the data during the second read operation.

13. A non-transitory computer-readable medium storing code comprising instructions, which, when executed by one or more processors of a memory system, cause the memory system to:
initialize an error recovery procedure in response to a failure to correct data read the memory system during a first read operation, the first read operation being performed using a first read voltage;
identify, as part of the error recovery procedure, a first read offset from a plurality of read offsets according to a first syndrome weight generated as part of an attempt to correct the data; and
perform, as part of the error recovery procedure, a second read operation to obtain the data, wherein the second read operation is performed using a second read voltage that comprises the first read voltage modified by the first read offset.

14. The non-transitory computer-readable medium of claim 13, wherein the instructions, when executed by the one or more processors of the memory system, further cause the memory system to:
determine that the first syndrome weight is less than a threshold, wherein identifying the first read offset from the plurality of read offsets is in accordance with the first syndrome weight being less than the threshold.

15. The non-transitory computer-readable medium of claim 14, wherein the instructions, when executed by the one or more processors of the memory system, further cause the memory system to:
skip one or more initial steps of the error recovery procedure in accordance with the first syndrome weight being less than the threshold, wherein identifying the first read offset is in accordance with skipping the one or more initial steps of the error recovery procedure.

16. The non-transitory computer-readable medium of claim 13, wherein, to identify the first read offset, the instructions, when executed by the one or more processors of the memory system, cause the memory system to:
identify, from a plurality of mappings, a first mapping comprising the plurality of read offsets in accordance with a voltage distribution that represents the data stored at a memory cell, in accordance with a portion of a logical address associated with the memory cell, or both, wherein identifying the first read offset from the plurality of read offsets is in accordance with identifying the first mapping comprising the plurality of read offsets.

17. The non-transitory computer-readable medium of claim 16, wherein each of the plurality of mappings are comprise respective pluralities of read offsets indexed by a respective range of syndrome weight values, each of the plurality of mappings are associated with a respective portion of the logical address, and each of the plurality of mappings are associated with a respective upper voltage valley of a plurality of upper voltage valleys, the respective upper voltage valley being between two voltage distributions.

18. The non-transitory computer-readable medium of claim 16, wherein each of the plurality of mappings are stored in volatile memory of the memory system.

19. The non-transitory computer-readable medium of claim 13, wherein the instructions, when executed by the one or more processors of the memory system, further cause the memory system to:
adjust the first read offset by a first adjustment coefficient of a plurality of adjustment coefficients, wherein performing the second read operation is in accordance with adjusting the first read offset by the first adjustment coefficient.

20. The non-transitory computer-readable medium of claim 19, wherein the instructions, when executed by the one or more processors of the memory system, further cause the memory system to:
identify a mapping comprising the plurality of adjustment coefficients in accordance with a portion of a logical address associated with the data, in accordance with a voltage valley between two voltage distributions of a memory cell that stores the data, or both, wherein one of the two voltage distributions of the memory cell represents the data; and
identify, from the plurality of adjustment coefficients included in the mapping, the first adjustment coefficient in accordance with a word line group associated with the memory cell.

21. The non-transitory computer-readable medium of claim 20, wherein:
the first adjustment coefficient defines a linear relationship between the voltage valley between the two voltage distributions of the memory cell and a corresponding second voltage valley between two other voltage distributions of the memory cell, and
the two other voltage distributions are greater than the two voltage distributions.

22. A method at a memory system, comprising:
initializing an error recovery procedure in response to a failure to correct data read the memory system during a first read operation, the first read operation being performed using a first read voltage;
identifying, as part of the error recovery procedure, a first read offset from a plurality of read offsets according to a first syndrome weight generated as part of an attempt to correct the data; and
performing, as part of the error recovery procedure, a second read operation to obtain the data, wherein the second read operation is performed using a second read voltage that comprises the first read voltage modified by the first read offset.
